(19) United States
(12) Patent Application Publication
(10) Pub. No.: US 2010/0093183 A1
(43) Pub. Date: Apr. 15, 2010

(54) UNIT FOR SUPPLYING CHEMICAL LIQUID AND APPARATUS AND METHOD FOR TREATING SUBSTRATE USING THE SAME

(76) Inventors: Dae Sung Kim, Gyeonggi-do (KR); In Cheol Ryu, Jeollabuk-do (KR)

Correspondence Address: JENKINS, WILSON, TAYLOR & HUNT, P. A., Suite 1200 UNIVERSITY TOWER, 3100 TOWER BLVD.,, DURHAM, NC, 27707, US

(21) Appl. No.: 12/570,538

(22) Filed: Sep. 30, 2009

(30) Foreign Application Priority Data
Oct. 9, 2008 (KR) 10-2008-0099229

(51) Int. Cl. H01L 21/461; B05C 11/00

(52) U.S. Cl. 438/759; 118/72; 118/600; 257/E21.483

(57) ABSTRACT

Provided are a unit for supplying chemical liquid, and apparatus and method for treating a substrate using the unit. A pre-wet, photoresist, and edge bead removal nozzles are mounted on a single nozzle body. Therefore, the equipment installing space can be saved as compared with a case where the nozzles are installed on respective nozzle arms, thereby making better use of a space for installing equipments.

### CROSS-REFERENCE TO RELATED APPLICATIONS

This U.S. non-provisional patent application claims priority under 35 U.S.C. §119 of Korean Patent Application No. 2008-0099229 filed on Oct. 9, 2008, the entire contents of which are hereby incorporated by reference.

### BACKGROUND OF THE INVENTION

The present invention described herein relates to a unit for supplying chemical liquid, and apparatus and method for treating a substrate using the same and, more particularly, to a unit for supplying chemical liquid used in a process for coating photoresist, and apparatus and method for treating a substrate using the unit.

Generally, a semiconductor substrate is manufactured by layering thin films forming a predetermined circuit pattern on a silicon wafer. In order to form and layer the thin films, a plurality of unit processes such as a deposition process, a photolithography process, an etching process, and the like should be repeatedly performed.

The photolithography process among the unit processes is for forming a pattern on a wafer. The photolithography process includes a photoresist coating process, an exposing process, a developing process, and the like.

The photoresist depositing process is for evenly applying photoresist that is sensitive to light on a surface of the wafer. The exposing process is for exposing the circuit pattern, on which the photoresist is formed, by allowing light to pass through a corresponding circuit pattern on a mask using a stepper. The developing process is for selectively developing a photoresist layer portion of the wafer, which is exposed or not exposed to the light through the exposing process, using a developer.

The pattern is formed on the wafer through the deposition, exposing, and developing processes and an uppermost layer of the water is etched using the pattern on the wafer, thereby forming the device having the pattern.

### SUMMARY OF THE INVENTION

The present invention provides a unit for supplying chemical liquid, which can make better use of a space for installing equipments by installing nozzles for spraying liquids (organic solvent, photoresist, edge bead removing agent, and the like) on a single nozzle arm. The present invention provides apparatus and method for treating a substrate using the unit.

Embodiments of the present invention provide treating liquid supplying units including: a photoresist nozzle supplying photoresist onto a substrate; and an edge bead removal nozzle supplying edge bead removal liquid to an edge of the substrate to remove an edge bead formed on the edge of the substrate, wherein the photoresist nozzle and the edge bead removal nozzle are mounted on a single nozzle arm.

In some embodiments, the treating liquid supplying units may further include a pre-wet nozzle that supplies organic solvent to the substrate to improve wetness of the photoresist supplied from the photoresist nozzle to the substrate, wherein the pre-wet nozzle may be mounted on the nozzle arm.

In other embodiments, the pre-wet nozzle, the photoresist nozzle, and the edge bead removal nozzle may be arranged inline at an end of the nozzle arm along a line perpendicular to a length direction of the nozzle arm.

In still other embodiments, the photoresist nozzle may be disposed on a center of a first end of the nozzle arm and the pre-wet nozzle and the edge bead removal nozzle may be respectively disposed at both sides of the photoresist nozzle.

In even other embodiments, the treating liquid supplying units may further include: a photoresist supplying source; a photoresist supplying line connecting the photoresist supplying source to the photoresist nozzle; an edge bead removal liquid supplying source; an edge bead removal liquid supplying line connecting the edge bead removal liquid supplying source to the edge bead removal nozzle; an organic solvent supplying source; and an organic solvent supplying line connecting the organic solvent supplying source to the pre-wet nozzle.

In other embodiments of the present invention, substrate treating apparatuses include: a substrate supporting member supporting a substrate; and a treating liquid supplying unit for processing a photoresist deposition process for the substrate supported on the substrate supporting member, wherein the treating liquid supplying unit includes: a photoresist nozzle supplying photoresist onto the substrate; and an edge bead removal nozzle supplying edge bead removal liquid to an edge of the substrate to remove an edge bead formed on the edge of the substrate, wherein the photoresist nozzle and the edge bead removal nozzle are mounted on a single nozzle arm.

In some embodiments, the treating liquid supplying units may further include a pre-wet nozzle that supplies organic solvent to the substrate to improve wetness of the photoresist supplied from the photoresist nozzle to the substrate, wherein the pre-wet nozzle may be mounted on the nozzle arm.

In other embodiments, the pre-wet nozzle, the photoresist nozzle, and the edge bead removal nozzle may be arranged inline at an end of the nozzle arm along a line perpendicular to a length direction of the nozzle arm.

In still other embodiments, the photoresist nozzle may be disposed on a center of a first end of the nozzle arm and the pre-wet nozzle and the edge bead removal nozzle may be respectively disposed at both sides of the photoresist nozzle.

In still yet other embodiments, the nozzle arm may be disposed at a side of the substrate supporting member such that the arranging direction of the pre-wet, photoresist, and edge bead removal nozzles can pass through the center of the substrate on the substrate supporting member.

In still further other embodiments, the substrate treating apparatuses may further include: a driving member that linearly moves the nozzle arm to move the pre-wet, photoresist, and edge bead removal nozzles to a process location on the substrate disposed on the substrate supporting member, wherein the driving member may include: a nozzle arm supporting member supporting the nozzle arm; a driving unit that reciprocally moves the nozzle arm supporting member; and a guide member guiding the linear motion of the nozzle arm supporting member.

In still further yet other embodiments, the treating liquid supplying unit may further include: a photoresist supplying source; a photoresist supplying line connecting the photoresist supplying source to the photoresist nozzle; an edge bead removal liquid supplying source; an edge bead removal liquid supplying line connecting the edge bead removal liquid supplying source to the edge bead removal nozzle; an organic solvent supplying source; and an organic solvent supplying line connecting the organic solvent supplying source to the pre-wet nozzle.

In still other embodiments of the present invention, methods for performing a photoresist deposition process for a substrate using the above-described substrate treating apparatus include: supplying the organic solvent to the center of the substrate by locating the pre-wet nozzle above the center of the substrate by moving the nozzle arm; supplying the photoresist to the center of the substrate by locating the photoresist nozzle above the center of the substrate by moving the nozzle; supplying the edge bead removal liquid to the edge of the substrate by locating the edge bead removal nozzle above the edge of the substrate by moving the nozzle arm, wherein the organic solvent, photoresist, and edge bed removal liquid are supplied while rotating the substrate.

In some embodiments, the pre-wet nozzle, the photoresist nozzle, and the edge bead removal nozzle are arranged inline at an end of the nozzle arm along a line perpendicular to a length direction of the nozzle arm; and the organic solvent and photoresist are sequentially supplied to the center of the substrate while moving the nozzle arm in an arranging direction of the nozzles and then the edge bead removal liquid is supplied to the edge of the substrate.

### BRIEF DESCRIPTION OF THE FIGURES

The accompanying figures are included to provide a further understanding of the present invention, and are incorporated in and constitute a part of this specification. The drawings illustrate exemplary embodiments of the present invention and, together with the description, serve to explain principles of the present invention. In the figures:

FIG. 1 is a top plan view of a semiconductor manufacturing facility with a substrate treating apparatus according to an embodiment of the present invention;

FIG. 2 is a side view of the semiconductor manufacturing facility of FIG. 1;

FIG. 3 is a view illustrating a process treating unit of the semiconductor manufacturing facility of FIG. 1;

FIG. 4 is a top plan view of a treating module for the deposition process among treating modules;

FIG. 5 is a side sectional view of the treating module of FIG. 4;

FIG. 6 is a front view of a portion A in FIG. 4; and

FIGS. 7A to 7C are views illustrating operation states of the substrate treating apparatus according to an embodiment.

### DETAILED DESCRIPTION OF PREFERRED EMBODIMENTS

Preferred embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. In the figures, the shapes of elements are exaggerated for clarity of illustration.

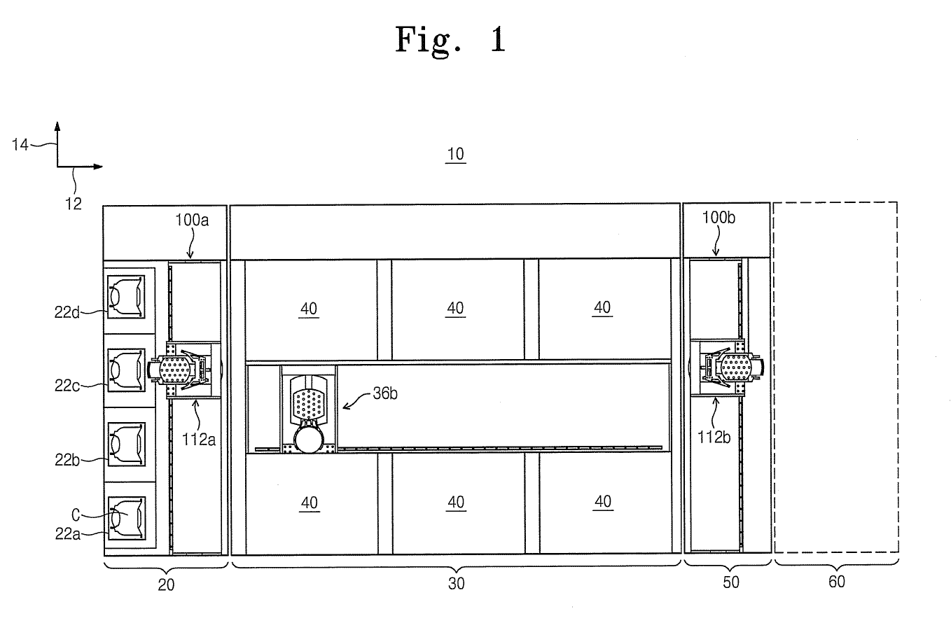

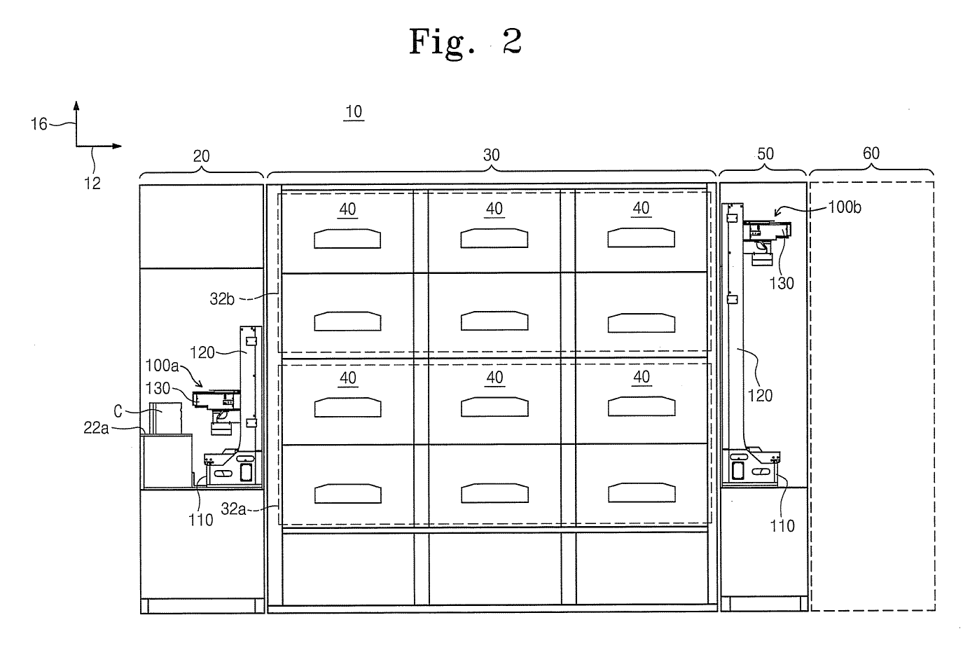

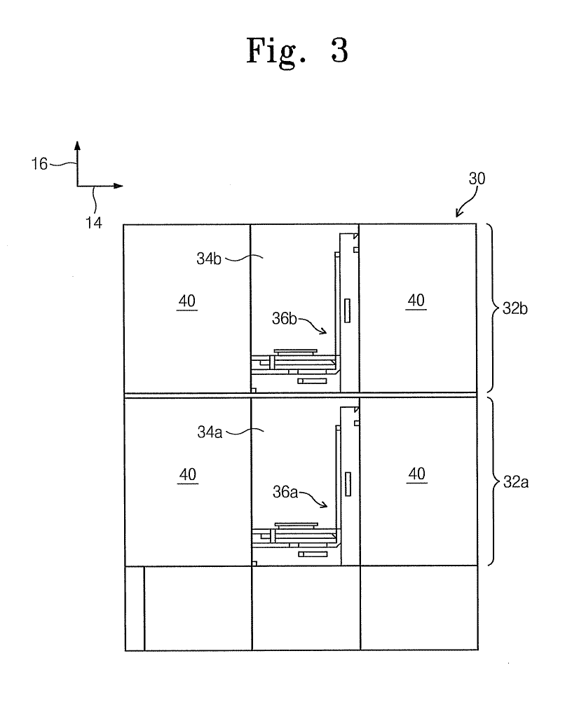

FIG. 1 is a top plan view of a semiconductor manufacturing facility with a substrate treating apparatus according to an embodiment of the present invention, FIG. 2 is a side view of the semiconductor manufacturing facility of FIG. 1, and FIG. 3 is a view illustrating a process treating unit of the semiconductor manufacturing facility of FIG. 1;

Referring to FIGS. 1 to 3, a semiconductor manufacturing facility 10 includes an index 20, a process treating unit 30, and an interface 50. The index 20, process treating unit 30, and interface 50 are arranged in a line extending in a first direction 12. The index 20 is disposed adjacent to a front end of the process treating unit 30 along the line extending in the first direction 12. The interface 50 is disposed adjacent to a rear end of the process treating unit 30 along the line extending in the first direction 12. The index 20 and interface 50 have lengths extending in a second direction 14 perpendicular to the first direction 12. The process treating unit 30 has a duplex structure in an up-down direction. A first treating unit 32a is disposed at a lower layer and a second treating unit 32b is disposed at an upper layer. The index 20 and interface 50 takes the substrate into or out of the process treating unit 30.

The first treating unit 32a includes a first transferring path 34a, a first main robot 36a, and treating modules 40. The first transferring path 34a extends from a location adjacent to the index 20 to a location adjacent to the interface 50 in the first direction 12. The treating modules 40 are arranged along the first transferring path 34a at both sides of the first transferring path 34a. The first main robot 36a is installed on the first transferring path 34a. The first main robot 36a transfers the substrate between the index 20, process modules 40, and interface 50.

The second treating unit 32b includes a second transferring path 34b, a second main robot 36b, and treating modules 40. The second transferring path 34b extends from a location adjacent to the index 20 to a location adjacent to the interface 50 in the first direction 12. The treating modules 40 are arranged along the second transferring path 34b at both sides of the second transferring path 34b. The second main robot 36b is installed on the second transferring path 34b. The second main robot 36b transfers the substrate between the index 20, process modules 40, and interface 50.

The first treating unit 32a may include modules for a deposition process. The second treating unit 32b may include modules for a developing process. Alternatively, the first treating unit 32a may include modules for a developing process. The second treating unit 32b may include modules for a deposition process. Alternatively, each of the first and second treating units 32a and 32b include modules for both the deposition and developing processes.

The modules for the deposition process include, for example, a module for an adhesion process, a module for a cooling process, a module for a photoresist deposition process, and a module for a soft bake process. The modules for the developing process include, for example, a module for heating the exposed substrate to a predetermined temperature, a module for cooling the substrate, a module for removing an exposed or unexposed region of the substrate by supplying developing solution, and a module for a hard bake process.

The index 20 is installed at a front end of the process treating unit 30. The index 20 includes load ports 22a, 22b, 22c, and 22d on which a cassette C receiving the substrates are disposed, and an index robot 100a. The load ports 22a, 22b, 22c, and 22d are disposed in series along a line extending in the second direction 14. The index robot 100a is located between the process treating unit 30 and the load ports 22a, 22b, 22c, and 22d. The cassette C receiving the substrates is transferred onto the load ports 22a, 22b, 22c, and 22d by a transferring unit (not shown) such as an overhead transfer, an overhead conveyor, or an automatic guided vehicle. An enclosed cassette such as a front open unified pod (FOUP) may be used as the cassette C. The robot 100a transfers the substrate between the cassette C disposed on the load ports 22a, 22b, 22c, and 22d and the process treating unit 30.

The interface 50 is installed at a rear end of the process treating unit 30 to be symmetrical with the index 20 with reference to the process treating unit 30. The interface 50 has an interface robot 100b. The interface robot 100b transfers the substrate between the exposing treating unit connected to the rear end of the interface 50 and the process treating unit 30.

The index robot 100a includes a horizontal guide 110, a vertical guide 120, and a robot arm 130. The robot arm 130 is capable of linearly moving in the first direction 12 and rotating about a Z-axis. The horizontal guide 110 guides linear motion of the robot arm 130 in the second direction 14. The vertical guide 120 guides linear motion of the robot arm 130 in a third direction 16. The robot arm 130 linearly moves in the second direction 14 along the horizontal guide 110, rotates about the Z-axis, and moves in the third direction. The interface robot 110b has a same structure as the index robot 100a.

The following will describe operation of the semiconductor manufacturing facility 10 structured as described above. The cassette C is transferred onto the rod port 22a of the index 20 by an operator or the transferring unit (not shown). The index robot 100a takes the substrate out of the cassette C and hands the substrate over to the first main robot 36a of the first treating unit 32a. The first main robot 36a moves along the first transferring path 34a and loads the substrate on the treating modules 40, after which the deposition process is performed. After the substrate is treated on the treating modules 40, the treated substrate is unloaded from the treating modules 40. The unloaded substrate is transferred to the interface robot 100b by the first main robot 36a. The interface robot 100b transfers the substrate to the exposing treating unit 60. The substrate that is treated in the exposing treating unit 60 is transferred to the second treating unit 32b by the interface robot 100b. The substrate is transferred to the treating modules 40 by the second main robot 36b, after which the developing process is performed. The developed substrate is transferred to the index 20.

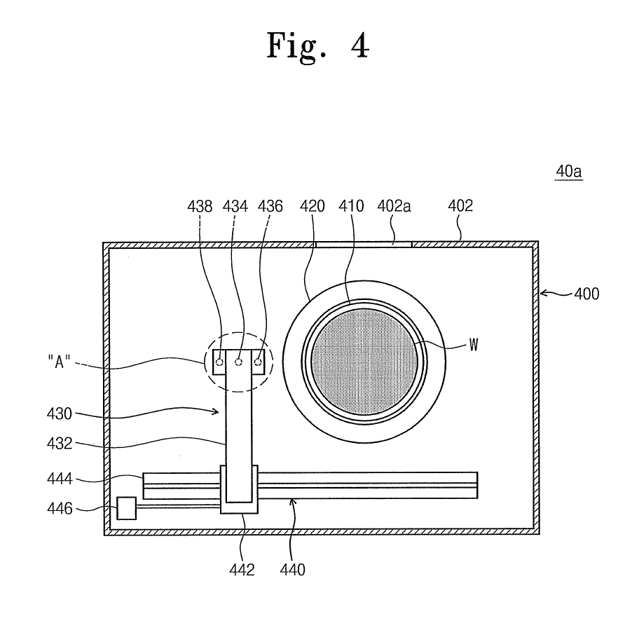

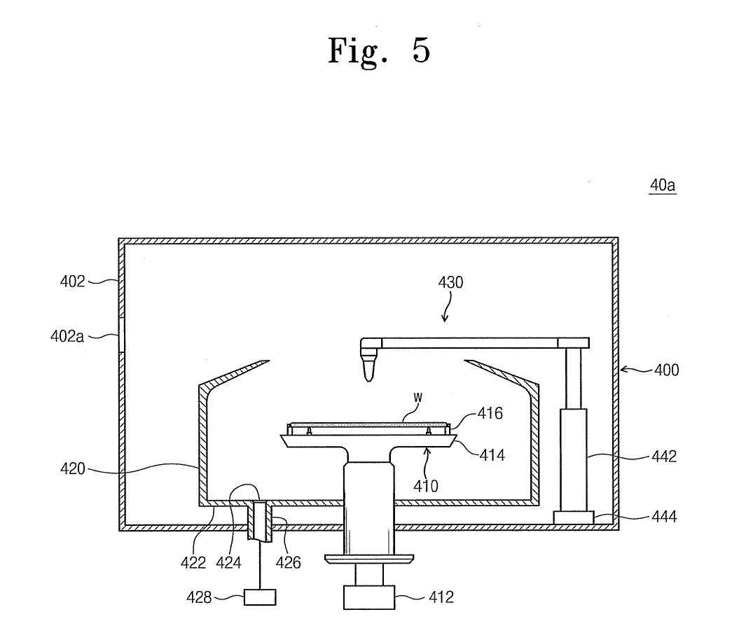

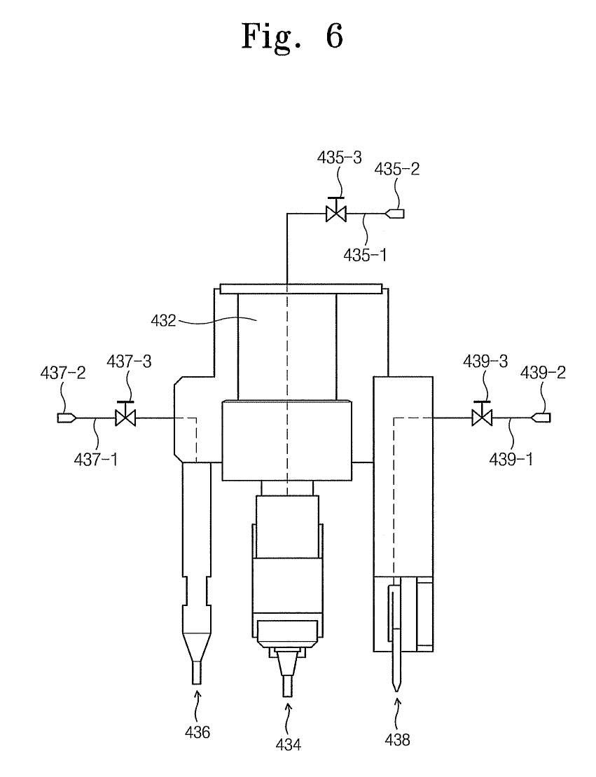

FIG. 4 is a top plan view of the treating module 40a for the deposition process among the treating modules 40, FIG. 5 is a side sectional view of the treating module 40a of FIG. 4, and FIG. 6 is a front view of a portion A in FIG. 4.

Referring to FIGS. 4 to 6, the treating module 40a includes a treating chamber 400, a substrate supporting member 410, and a treating liquid supplying unit 430. The treating chamber 400 provides a space in which the substrate treating process is performed. An opening 402a is formed through a sidewall of the treating chamber 400 so that the substrate W can go in and out of the treating chamber 400 through the opening 402a. The substrate supporting member 410 is disposed at a central portion of the treating chamber 400. The substrate supporting member 410 supports the substrate W and rotates the substrate W. The treating liquid supplying unit supplies the treating liquid onto the substrate W on the substrate supporting member 410 to treat the substrate W.

The substrate supporting member 410 supports the substrate W and rotates by a rotating driving member 412 such as a motor during the process. The substrate supporting member 410 includes a supporting plate 414 having a circular top surface. Pin members 416 supporting the substrate W are installed on the top surface of the supporting plate 414. The substrate W supported by the pin members 416 rotates as the substrate supporting member 410 rotates by the rotating driving member 412.

A container 420 is disposed around the substrate supporting member 410. The container 420 is substantially formed in a cylindrical shape and provided at a lower wall 422 thereof with a discharge hole 424. A discharge pipe 426 is connected to the discharge hole 424. A discharge member 428 such as a pump is connected to the discharge pipe 426. Negative pressure is applied to the discharge member 428 so that fluid containing the liquid scattered by the rotation of the substrate W in the container 420 can be discharged.

The treating liquid supplying unit 430 supplies the treating liquid onto the top surface of the substrate W on the substrate supporting member 410. The treating liquid supplying unit 430 includes a nozzle arm 432 on a side of the substrate supporting member 410. A plurality of nozzles 434, 436, and 438 may be mounted on an end of the nozzle arm 432. The nozzles 434, 436, and 438 may be arranged in series on the end of the nozzle arm 432 along a line perpendicular to the length direction of the nozzle arm 432. A photoresist nozzle 344 is mounted on a center of the end of the nozzle arm 432. A pre-wet nozzle 436 and an edge bead removal nozzle 438 may be respectively mounted at both sides of the end of the nozzle arm 432. The nozzle arm 432 may be disposed at a side of the substrate supporting member 410 such that the arranging direction of the nozzles 434, 436, and 438 can pass through the center of the substrate W on the substrate supporting member 410.

The photoresist nozzle 434 supplies the photoresist onto the substrate W. The pre-wet nozzle 436 supplies an organic solvent onto the substrate W before the photoresist is provided onto the substrate W, thereby improving the wetness of the photoresist. When the organic solvent is provided onto the substrate before the photoresist is provided onto the substrate, the photoresist are evenly distributed to evenly form the photoresist layer on the substrate.

The edge bead removal nozzle 438 supplies edge bead removal liquid to an edge of the substrate W to remove the edge bead on the edge of the substrate W. Since the photoresist has fluidity, the photoresist forcedly flows to the edge of the top surface of the substrate W by centrifugal force as the substrate W rotates at high speed. The photoresist directed to the edge of the substrate W forms the edge bead as it more swells up than other portions. The edge bead may be adhered to, for example, the cassette to function as a polluting material in the following processes. Therefore, the edge bead must be removed after applying the photoresist. The edge bead removal nozzle 438 supplies edge bead removal liquid to remove the edge bead.

The photoresist nozzle 434 is connected to a photoresist supplying source 435-2 by a photoresist supplying line 435-1. A valve 435-3 for selectively opening or closing the photoresist supplying line 435-1 may be installed on the photoresist supplying line 435-1. The edge bead removal nozzle 438 is connected to an edge bead removal liquid supplying source 439-2 by an edge bead removal liquid supplying line 439-1. A valve 439-3 for selectively opening or closing the edge bead removal liquid supplying line 439-1 may be installed on the edge bead removal supplying line 439-1.

For example, thinner may be used as the organic solvent supplied from the pre-wet nozzle 436 to the substrate and the edge bead removal liquid supplied from the edge bead removal nozzle 438 to the substrate.

The nozzle arm 432 on which the nozzles 434, 436, and 438 are mounted may linearly move by the driving member 440 in accordance with the arranging direction of the nozzles 434, 436, and 438. The driving member 440 includes a nozzle arm supporting member 442, a guide member 444, and a driving unit 446. The nozzle arm supporting member 442 is coupled to the other end of the nozzle arm 432. The nozzle supporting member 442 may be provided in the form of a moving rod that is vertically arranged downward to maintain a right angle to the nozzle arm 432. A lower end of the nozzle arm supporting member 442 is connected to the guide member 444. The guide member 444 is disposed at a side of the substrate supporting member 410 to be perpendicular to the length direction of the nozzle arm 432 in the top-plan arranging structure of FIG. 4. The guide member 444 may be provided in the form of a guide rail to guide the linear motion of the nozzle arm supporting member 442. In addition, the driving unit 446 for the linear motion of the nozzle arm supporting member 442 is connected to the nozzle arm supporting member 442. A linear reciprocation mechanism such as a cylinder may be used as the driving unit 446. Alternatively, a combination of a motor and gears may be used as the driving unit 446. The nozzle arm supporting member 442 may linearly move in the vertical direction by a driving member (not shown).

The treating liquid supplying unit 430 moves linearly by the driving member 440 to be located at process locations (pre-wet organic solvent/photoresist supplying locations, edge bead removal liquid supplying location) and a process standby location provided at a side of the substrate supporting member 410. The pre-wet organic solvent supplying location is a location where the pre-wet nozzle 436 is aligned with a central portion of the substrate. The photoresist supplying location is a location where the photoresist nozzle 434 is aligned with the central portion of the substrate. In addition, the edge bead removal liquid supplying location is a location where the edge bead removal nozzle 438 is aligned with the edge of the substrate.

The following will describe a method for treating a substrate using the above-described substrate treating apparatus according to an embodiment.

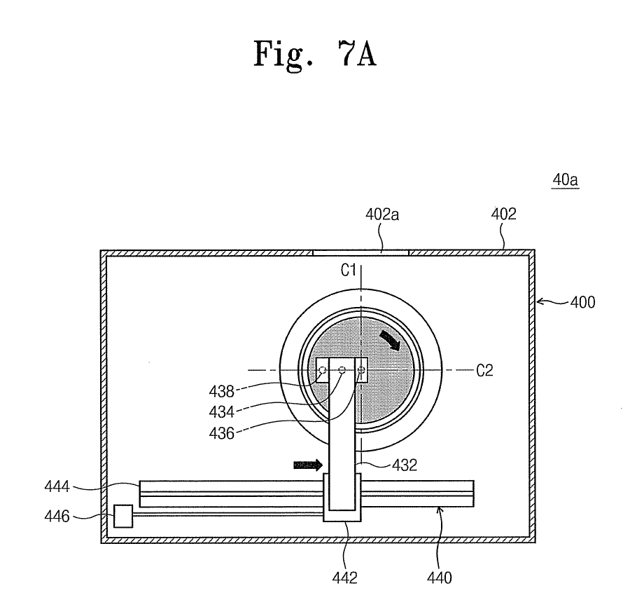

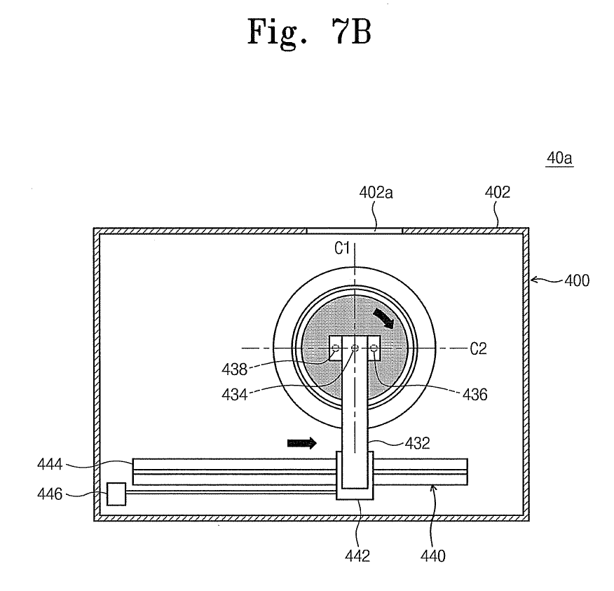

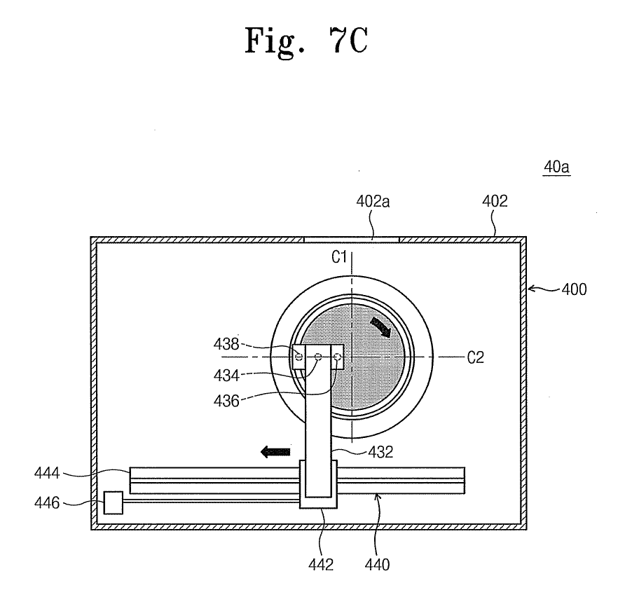

FIGS. 7A to 7C are views illustrating operation states of the substrate treating apparatus according to an embodiment.

First, the substrate W is transferred into the treating chamber 400 through the opening 402a of the treating chamber 400 and disposed on the substrate supporting member 410. Next, the nozzle arm supporting member 442 to which the nozzle arm 432 is coupled linearly moves by the guide of the guide member 44 and thus the nozzle arm 432 moves to the pre-wet organic solvent supplying location on the substrate. The pre-wet organic solvent supplying location is the location where the pre-wet nozzle 436 is aligned with the central portion of the substrate. Here, the central portion of the substrate is an intersection point of imaginary lines C1 and C2 extending in a diameter direction of the substrate. The nozzle arm supporting member 442 moves in the vertical direction by the driving member (not shown) and thus the pre-wet nozzle 436 mounted on the nozzle arm 432 maintains a predetermined gap with the substrate on the substrate supporting member 410.

The pre-wet nozzle 436 pours the organic solvent onto the substrate and the rotating driving member 412 (see FIG. 5) rotates the substrate supporting member 410 to rotate the substrate W. The organic solvent scattered by the rotation of the substrate W is discharged to an external side through the discharge pipe 426 of the container 420 (see FIG. 7A).

When the pre-wet process supplying the organic solvent onto the substrate W is completed, the nozzle arm supporting member 442 to which the nozzle arm 432 is coupled is guided by the guide member 444 to move linearly. Accordingly, the nozzle arm 432 moves to the photoresist supplying location. The photoresist supplying location is the location where the photoresist nozzle 434 is aligned with the central portion of the substrate. Next, the photoresist nozzle 434 mounted on the nozzle arm 432 pours the photoresist onto the substrate W. At this point, the substrate W keeps rotating (see FIG. 7B).

When the photoresist deposition process for supplying the photoresist onto the substrate W is completed, the nozzle arm supporting member 442 to which the nozzle arm 432 is coupled is guided by the guide member 444 to linearly move. Accordingly, the nozzle arm 432 moves to the edge bead removal liquid supplying location on the substrate. The edge bead removal liquid supplying location is the location where the edge bead removal nozzle 438 is aligned with the edge of the substrate. Next, the edge bead removal nozzle 438 mounted on the nozzle arm 432 pours the edge bead removal liquid (organic solvent) to the edge of the substrate W. At this point, the substrate W keeps rotating (see FIG. 7C).

When the edge bead removal process is completed, the nozzle arm supporting member 442 to which the nozzle arm 432 is coupled is guided by the guide member 444 to linearly move. Therefore, the nozzle arm 432 moves to a process standby location at a side of the substrate supporting member 410.

A feature of the above-described substrate treating apparatus according to the embodiment is that the pre-wet nozzle, photoresist nozzle, and edge bead removal nozzle are mounted on the single nozzle arm.

According to the feature, the equipment installing space can be saved as compared with the case where the nozzles are installed on respective nozzle arms, thereby making better use of a space for installing equipments.

In addition, when the pre-wet process, photoresist supplying process, and edge bead removal process are consecutively performed, the process time for the nozzle selection can be reduced.

Although the embodiment describes only a local spinner facility that can perform only the deposition and developing processes as the semiconductor manufacturing facility 10 having the substrate treating apparatus, the present invention is not limited to this. That is, the substrate treating apparatus of the present invention can be associated with an exposing system so that it can be applied to an inline spinner facility that can consecutively perform the deposition, exposing, and developing processes.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A treating liquid supplying unit comprising:
a photoresist nozzle supplying photoresist onto a substrate; and
an edge bead removal nozzle supplying edge bead removal liquid to an edge of the substrate to remove an edge bead formed on the edge of the substrate,
wherein the photoresist nozzle and the edge bead removal nozzle are mounted on a single nozzle arm.

2. The treating liquid supplying unit of claim 1, further comprising a pre-wet nozzle that supplies organic solvent to the substrate to improve wetness of the photoresist supplied from the photoresist nozzle to the substrate.

3. The treating liquid supplying unit of claim 2, wherein the pre-wet nozzle, the photoresist nozzle, and the edge bead removal nozzle are arranged inline at an end of the nozzle arm along a line perpendicular to a length direction of the nozzle arm.

4. The treating liquid supplying unit of claim 3, wherein the photoresist nozzle is disposed on a center of a first end of the nozzle arm; and
the pre-wet nozzle and the edge bead removal nozzle are respectively disposed at both sides of the photoresist nozzle.

5. The treating liquid supplying unit of claim 2, further comprising:
a photoresist supplying source;
a photoresist supplying line connecting the photoresist supplying source to the photoresist nozzle;
an edge bead removal liquid supplying source;
an edge bead removal liquid supplying line connecting the edge bead removal liquid supplying source to the edge bead removal nozzle;
an organic solvent supplying source; and
an organic solvent supplying line connecting the organic solvent supplying source to the pre-wet nozzle.

6. A substrate treating apparatus comprising:
a substrate supporting member supporting a substrate; and
a treating liquid supplying unit for processing a photoresist deposition process for the substrate supported on the substrate supporting member,
wherein the treating liquid supplying unit comprises:
a photoresist nozzle supplying photoresist onto the substrate; and
an edge bead removal nozzle supplying edge bead removal liquid to an edge of the substrate to remove an edge bead formed on the edge of the substrate,
wherein the photoresist nozzle and the edge bead removal nozzle are mounted on a single nozzle arm.

7. The substrate treating apparatus of claim 6, wherein the treating liquid supplying unit further comprises a pre-wet nozzle that supplies organic solvent to the substrate to improve wetness of the photoresist supplied from the photoresist nozzle to the substrate.

8. The substrate treating apparatus of claim 7, wherein the pre-wet nozzle, the photoresist nozzle, and the edge bead removal nozzle are arranged inline at an end of the nozzle arm along a line perpendicular to a length direction of the nozzle arm.

9. The substrate treating apparatus of claim 8, wherein the photoresist nozzle is disposed on a center of a first end of the nozzle arm; and
the pre-wet nozzle and the edge bead removal nozzle are respectively disposed at both sides of the photoresist nozzle.

10. The substrate treating apparatus of claim 7, wherein the nozzle arm is disposed at a side of the substrate supporting member such that the arranging direction of the pre-wet, photoresist, and edge bead removal nozzles can pass through the center of the substrate on the substrate supporting member.

11. The substrate treating apparatus of claim 10, further comprising:
a driving member that linearly moves the nozzle arm to move the pre-wet, photoresist, and edge bead removal nozzles to a process location on the substrate disposed on the substrate supporting member,
wherein the driving member comprises:
a nozzle arm supporting member supporting the nozzle arm;
a driving unit that reciprocally moves the nozzle arm supporting member; and
a guide member guiding the linear motion of the nozzle arm supporting member.

12. The substrate treating apparatus of claim 7, wherein the treating liquid supplying unit further comprises:
a photoresist supplying source;
a photoresist supplying line connecting the photoresist supplying source to the photoresist nozzle;
an edge bead removal liquid supplying source;
an edge bead removal liquid supplying line connecting the edge bead removal liquid supplying source to the edge bead removal nozzle;
an organic solvent supplying source; and
an organic solvent supplying line connecting the organic solvent supplying source to the pre-wet nozzle.

13. A method for performing a photoresist deposition process for a substrate using the apparatus of claim 7, comprising:
supplying the organic solvent to the center of the substrate by locating the pre-wet nozzle above the center of the substrate by moving the nozzle arm;
supplying the photoresist to the center of the substrate by locating the photoresist nozzle above the center of the substrate by moving the nozzle;
supplying the edge bead removal liquid to the edge of the substrate by locating the edge bead removal nozzle above the edge of the substrate by moving the nozzle arm,
wherein the organic solvent, photoresist, and edge bed removal liquid are supplied while rotating the substrate.

14. The method of claim 13, wherein the pre-wet nozzle, the photoresist nozzle, and the edge bead removal nozzle are arranged inline at an end of the nozzle arm along a line perpendicular to a length direction of the nozzle arm; and
the organic solvent and photoresist are sequentially supplied to the center of the substrate while moving the nozzle arm in an arranging direction of the nozzles and then the edge bead removal liquid is supplied to the edge of the substrate.
